(19) United States
(12) Patent Application Publication
(10) Pub. No.: US 2024/0319238 A1
(43) Pub. Date: Sep. 26, 2024

(54) VOLTAGE FILTERING METHOD FOR DETECTING POINT IN CIRCUIT, SWITCH STATE DETECTING METHOD, AND RELATED APPARATUS

(71) Applicant: Changchun Jetty Automotive Technology Co., Ltd., Changchun, Jilin Province (CN)

(72) Inventors: Chao WANG, Changchun (CN); Dongping CHEN, Changchun (CN)

(21) Appl. No.: 18/578,260

(22) PCT Filed: Jul. 21, 2022
(86) PCT No.: PCT/CN2022/107008

§ 371 Date: Jan. 10, 2024

(30) Foreign Application Priority Data
Jul. 23, 2021 (CN) 202110839634.6

(51) Int. Cl. G01R 19/25; G01R 19/10

(52) U.S. Cl. CPC G01R 19/2506; G01R 19/10

(57) ABSTRACT

A voltage filtering method for a detecting point in a circuit, a switch state detection method and a related apparatus, which may be used in the technical field of new energy, the voltage filtering method for a detecting point in a circuit including: continuously collecting multiple voltage data of a detecting point in a target circuit; respectively obtaining a plurality of voltage filtering values corresponding to the detecting point by preforming filter modes based on the multiple voltage data; comparing the plurality of voltage filtering values, and if the corresponding comparison result meets a preset condition, determining a voltage target value of the detecting point based on the plurality of voltage filtering values. The present disclosure effectively verifies the validity of the voltage filtering for the detecting point in the circuit, and then ensures the reliability of the voltage filtering for the detecting point, thereby effectively improving the accuracy and reliability of subsequent control or detection according to the filtered voltage.

### RELATED APPLICATION

The present application claims the priority of Chinese Patent Application No. 202110839634.6, filed on Jul. 23, 2021, which is hereby incorporated by reference in its entirety.

### TECHNICAL FIELD

The present disclosure relates to the technical field of new energy, and in particular to a voltage filtering method for a detecting point in a circuit, a switch state detection method and a related apparatus.

### BACKGROUND

The voltage filtering for a detecting point (DP) refers to that an analog signal of voltage collected from the detecting point in the circuit is converted into a digital signal and then filtered, to prevent the voltage jitter from causing the control misjudgment of the circuit. Especially for a control guidance unit of a charging base and etc. of new energy vehicles, the reliability of voltage filtering on the detecting point directly determines the detection accuracy of the switch state in the control guidance unit.

At present, the existing voltage filtering method for a detecting point configured with a single filter circuit and etc. to filter the ripple in the voltage. However, this method cannot verify the effectiveness of voltage filtering, and thus cannot guarantee the accuracy of subsequent control or detection based on the filtered voltage.

### SUMMARY

Aiming at the problems in the prior art, the present disclosure provides a method and a related apparatus for voltage filtering for a detecting point in a circuit and a switch state detection, all of which may effectively verify the validity of the voltage filtering for the detecting point in the circuit, and then ensure the reliability of the voltage filtering for the detecting point, and then effectively improve the accuracy and reliability of subsequent control or detection based on the filtered voltage.

In order to solve the above technical problems, the present disclosure provides the following technical solutions:

In a first aspect, the present disclosure provides a voltage filtering method for a detecting point in a circuit, including:
continuously collecting multiple voltage data of a detecting point in a target circuit;
respectively obtaining a plurality of voltage filtering values corresponding to the detecting point by preforming filter modes based on the multiple voltage data; and
comparing the plurality of voltage filtering values, and if the corresponding comparison result meets a preset condition, determining a voltage target value of the detecting point based on the plurality of voltage filtering values.

In a second aspect, the present disclosure provides a switch state detection method, including:
obtaining a voltage target value of a first detecting point after controlling a first switch to be closed, based on a voltage filtering method for a detecting point, wherein one end of the first switch is connected with a first resistor in the control guidance unit of a charging base, and the first detecting point is arranged at the other end of the first switch; and
determining whether the voltage target value of the first detecting point meets a first closing condition, and if so, determining that the first switch is currently in a closed state.

In a third aspect, the present disclosure provides a voltage filtering apparatus for a detecting point in a circuit, including:
a voltage collection module configured to continuously collect multiple voltage data of a detecting point in a target circuit;
a voltage filtering module configured to respectively obtain a plurality of voltage filtering values corresponding to the detecting point by preforming filter modes based on the multiple voltage data; and
a microcontroller configured to compare the plurality of voltage filtering values, and if the corresponding comparison result meets a preset condition, determine a voltage target value of the detecting point based on the plurality of voltage filtering values.

In a fourth aspect, the present disclosure provides a switch state detection system, including:
a voltage filtering apparatus for a detecting point configured to, obtain a voltage target value of a first detecting point after controlling a first switch to be closed, based on a voltage filtering method for a detecting point, and one end of the first switch is connected with a first resistor in the control guidance unit of a charging base, and the first detecting point is arranged at the other end of the first switch; and
a switch state determination module configured to determine whether the voltage target value of the first detecting point meets a first closing condition, and if so, determine that the first switch is currently in a closed state.

In a fifth aspect, the present disclosure provides an electronic device including a memory, a processor and a computer program stored in the memory and capable of running on the processor, and the computer program, when being executed by the processor, implements the voltage filtering method for a detecting point, or the computer program, when being executed by the processor, implements the switch state detection method.

In a sixth aspect, the present disclosure provides a computer-readable storage medium including a computer program stored thereon, when being executed by a processor, the computer program implements the voltage filtering method for a detecting point, or when being executed by the processor, the computer program implements the switch state detection method.

As can be seen from the above technical solution, the present disclosure provides a voltage filtering method for a detecting point in a circuit, a switch state detection method and a related apparatus, in which the voltage filtering method for a detecting point in a circuit includes: continuously collecting multiple voltage data of a detecting point in a target circuit: respectively obtaining a plurality corresponding voltage filtering values corresponding to the detecting point by preforming filter modes based on the multiple voltage data; and comparing the plurality of voltage filtering values, and if the corresponding comparison result meets a preset condition, determining a voltage target value of the detecting point based on the plurality of voltage filtering values, so effectively verifies the validity of the voltage filtering for the detecting point in the circuit, effectively ensures the reliability of the voltage filtering for the detecting point, and effectively and reliably prevents the voltage jitter from causing the control misjudgment of the circuit, thereby effectively improving the accuracy and reliability of subsequent control or detection based on the filtered voltage. Especially for a control guidance unit and etc. of a charging base of new energy vehicles, the accuracy of detecting the switch state in the control guidance unit based on the filtered voltage is improved, thereby effectively improving the work stability and reliability of the control guidance unit of the charging base of new energy vehicles.

### BRIEF DESCRIPTION OF THE DRAWINGS

To illustrate more clearly the embodiments of the present disclosure or the technical solutions of the prior art, a brief description of the accompanying drawings in the embodiments or the prior art will be given below. Obviously, the accompanying drawings described below are some embodiments described in this disclosure. For those of ordinary skill in the art, other drawings may also be obtained without any creative labor from these drawings.

FIG. 1 is a schematic diagram of a first flow of a voltage filtering method for a detecting point in a circuit according to an embodiment of the present disclosure.

FIG. 2 is a schematic diagram of a second flow of a voltage filtering method for a detecting point in a circuit according to an embodiment of the present disclosure.

FIG. 3 is a schematic diagram of a third flow of a voltage filtering method for a detecting point in a circuit according to an embodiment of the present disclosure.

FIG. 4 is a schematic diagram of a fourth flow of a voltage filtering method for a detecting point in a circuit according to an embodiment of the present disclosure.

FIG. 5 is a schematic diagram of a first flow of a switch state detection method according to an embodiment of the present disclosure.

FIG. 6 is an example diagram of a control guidance unit according to an embodiment of the present disclosure.

FIG. 7 is a schematic diagram of a second flow of a switch state detection method according to an embodiment of the present disclosure.

FIG. 8 is a schematic diagram of a third flow of a switch state detection method according to an embodiment of the present disclosure.

FIG. 9 is a schematic diagram of a fourth flow of a switch state detection method according to an embodiment of the present disclosure.

FIG. 10 is a structural schematic diagram of a voltage filtering apparatus for a detecting point in a circuit according to an embodiment of the present disclosure.

FIG. 11 is a first structural schematic diagram of a switch state detection system according to an embodiment of the present disclosure.

FIG. 12 is a second structural schematic diagram of a switch state detection system according to an embodiment of the present disclosure.

FIG. 13 is a flow schematic diagram of the switch state detection method that is realized based on the switch state detection system according to an application example of the present disclosure.

FIG. 14 is a structural schematic diagram of an electronic device according to an embodiment of the present disclosure.

### DETAILED DESCRIPTION

In order to more clearly illustrate purpose, technical solution and advantages of the embodiment of the present disclosure, hereinafter the technical solution in the embodiments of the present disclosure will be described clearly and integrally in combination with the accompanying drawings in the embodiments of the present disclosure, and obviously the described embodiments are merely part of the embodiments, not all of the embodiments. Any other embodiment obtained by those skilled in the art based on the embodiments of the present disclosure without paying any creative labor fall within the protection scope of the present disclosure.

It should be noted that the voltage filtering method for a detecting point in a circuit, the switch state detection method and apparatus disclosed in the present disclosure may be applied to the technical field of new energy, and may also be applied in any field other than the technical field of new energy. The method and related apparatus for voltage filtering for a detecting point in a circuit, and the switch state detection, and the system for the switch state detection, all of which are disclosed in the present disclosure may be applied in limitless field.

Considering that the existing voltage filtering method for a detecting point means using a single filtering circuit and etc. to filter the ripple in the voltage, this method cannot verify the effectiveness of voltage filtering, and thus cannot guarantee the accuracy of subsequent control or detection based on the filtered voltage. Embodiments of the present disclosure provide a method and an apparatus for voltage filtering method for a detecting point in a circuit, a method and an apparatus for switch state detection, all of which, by continuously collecting multiple voltage data of a detecting point in a target circuit: respectively obtaining a plurality of voltage filtering values corresponding to the detecting point by preforming filter modes based on the multiple voltage data; and comparing the plurality of voltage filtering values, and if the corresponding comparison result meets a preset condition, determining a voltage target value of the detecting point based on the plurality of voltage filtering values, so effectively verifies the validity of the voltage filtering for the detecting point in the circuit, effectively ensures the reliability of the voltage filtering for the detecting point, and effectively and reliably prevents the voltage jitter from causing the control misjudgment of the circuit, thereby effectively improving the accuracy and reliability of subsequent control or detection based on the filtered voltage. Especially for a control guidance unit and etc. of a charging base of new energy vehicles, the accuracy of detecting the switch state in the control guidance unit based on the filtered voltage is improved, thereby effectively improving the work stability and reliability of the control guidance unit of the charging base of new energy vehicles.

The details are illustrated by the following multiple embodiments.

In order to solve the problems that the existing voltage filtering method for a detecting point cannot verify the effectiveness of voltage filtering, and thus cannot guarantee the accuracy of subsequent control or detection based on the filtered voltage, an embodiment of the present disclosure provides a voltage filtering method for a detecting point in a circuit, with reference to FIG. 1, the voltage filtering method for a detecting point in a circuit specifically includes:

A step 110 of continuously collecting multiple voltage data of a detecting point in a target circuit.

In the step 110, the continuous collection refers to collecting the data a preset number of times during a preset period, such as 10 times in 0.3 S, and then 10 voltage data Vdp₁ to Vdp₁₀ for a detecting point are obtained.

It can be understood that the voltage data refers to a digital signal, and the collection process of the digital signal is: collecting a voltage analog signal of a collection point in a target circuit: then converting the voltage analog signal to a digital signal to obtain a digital signal for filtering processing in the subsequent step 200.

In one or more embodiments of the present disclosure, the target circuits refer to all circuits, such as switching circuits and etc., in which detecting points are arranged and voltage filtering is performed on the detecting points. In an example of the present disclosure, the target circuit may refer specifically to a control guidance unit of a charging base of a new energy vehicle, and the control guidance unit may refer to a circuit for performing switching control and guidance on the charging base of the new energy vehicle.

A step 120 of respectively obtaining a plurality of voltage filtering values corresponding to the detecting point by preforming filter modes based on the multiple voltage data.

In the step 120, two or more filter modes may be selected to process the plurality of voltage data respectively to obtain the voltage filtering values corresponding to the detecting point, and the number of the voltage filtering values is equal to the number of selected filter modes. For example, if four filter modes A, B, C, and D are selected, the filtering results corresponding to the four filter modes are obtained, namely, the voltage filtering values A1, B1, C1, and D1. In an example, the filter modes may be selected as at least two of mean filter, median filter, post-interpolation filter, post-dimensionality-reduction filter and neighborhood average filter modes.

A step 130 of comparing the plurality of voltage filtering values to obtain a corresponding comparison result.

A step 140 of, if the comparison result meets a preset condition, determining a voltage target value of the detecting point based on the plurality of voltage filtering values.

In the steps 130 and 140, the manner of comparing the plurality of voltage filtering values may include obtaining a difference value between the maximum value and the minimum value of the plurality of voltage filtering values, and taking the difference value as a comparison result to determine whether the difference value is smaller than a threshold value such as a preset error threshold value, and if it is, determining the voltage target value of the detecting point based on the plurality of voltage filtering values.

It can be understood that the manner of determining the voltage target value of the detecting point based on the plurality of voltage filtering values may include: calculating a mean value of the plurality of voltage filtering values and determining the mean value as a voltage target value of the detecting point: or selecting a median value of the plurality of voltage filtering values, and determining the median value as the voltage target value of the detecting point: or selecting any one of the plurality of voltage filtering values as the voltage target value of the detecting point.

As can be seen from the above description, the voltage filtering method for a detecting point provided in the embodiment of the present disclosure effectively verifies the validity of the voltage filtering for the detecting point in the circuit, effectively ensures the reliability of the voltage filtering for the detecting point, and effectively and reliably prevents the voltage jitter from causing the control misjudgment of the circuit, thereby effectively improving the accuracy and reliability of subsequent control or detection based on the filtered voltage. Especially for a control guidance unit and etc. of a charging base of new energy vehicles, the accuracy of detecting the switch state in the control guidance unit based on the filtered voltage is improved, thereby effectively improving the work stability and reliability of the control guidance unit of the charging base of new energy vehicles.

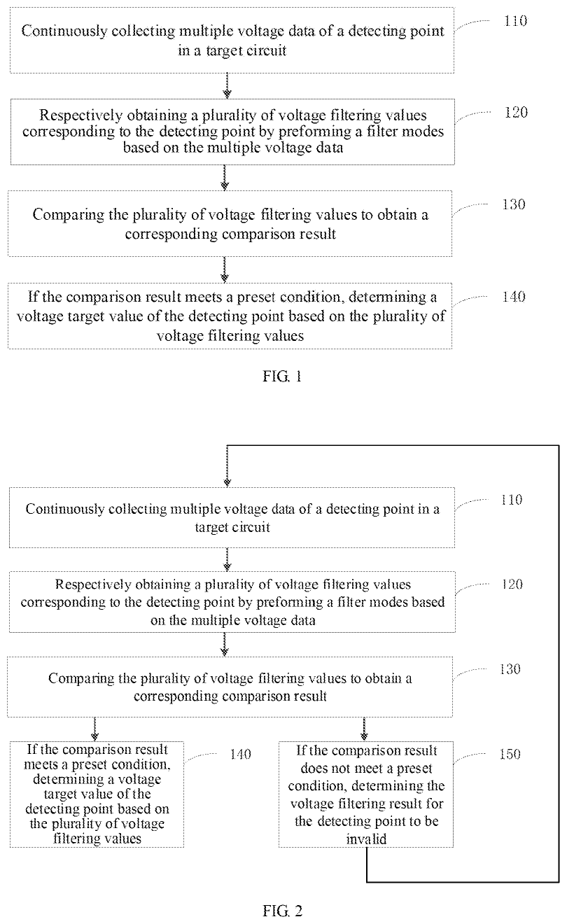

In order to provide a reliable processing method when it is verified that the voltage filtering result for the detecting point are invalid or unreliable, in an embodiment of the voltage filtering method for a detecting point in a circuit provided by the present disclosure, with reference to FIG. 2, subsequent to the step 130, the voltage filtering method for a detecting point in a circuit may further include:

A step 150 of, if the comparison result does not meet a preset condition, determining the voltage filtering result for the detecting point to be invalid;

Then returning to the step 110 and executing the steps 110 to 130 again of: continuously collecting multiple voltage data of the detecting point again and obtaining a plurality of voltage filtering values corresponding to the detecting point until the comparison results obtained again meet the preset condition, and executing the step 140 of determining the voltage target value of the detecting point.

As can be seen from the above description, by the voltage filtering method for a detecting point provided in the embodiment of the present disclosure, a reliable processing method is provided when it is verified that the voltage filtering result for the detecting point in the circuit are invalid or unreliable, to further ensure the reliability of voltage filtering for the detecting point, thus the method effectively and reliably prevents the voltage jitter from causing the control misjudgment of the circuit, and effectively improves the widely applicable property of the voltage filtering process for the detecting point.

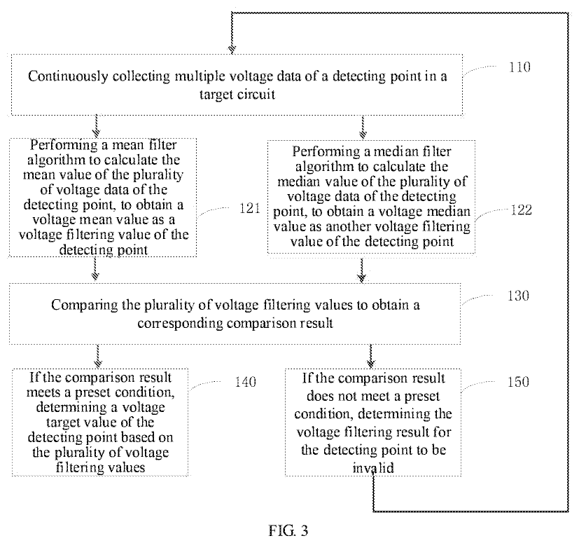

In order to reduce circuit complexity and reduce energy waste, in an embodiment of the voltage filtering method for a detecting point provided in this disclosure, with reference to FIG. 3, the step 120 of the voltage filtering method for a detecting point may specifically include:

A step 121 of performing a mean filter algorithm to calculate the mean value of the plurality of voltage data of the detecting point, to obtain a voltage mean value as a voltage filtering value of the detecting point.

For example, supposing that the detection point voltage is Vdp, taking n data of the detecting point, n is a positive integer: the sum of n data is Vdp_sum, then:

$$Vdp\_sum = {Vdp}_{1} + {Vdp}_{2} + {Vdp}_{3} + … + {Vdp}_{n - 1} + {Vdp}_{n} ;$$

supposing that the mean value of n data is Vdp_ave; then:

$$Vdp\_ave = Vdp\_sum / n .$$

A step 122 of performing a median filter algorithm to calculate the median value of the plurality of voltage data of the detecting point, to obtain a voltage median value as another voltage filtering value of the detecting point.

For example, supposing that the detection point voltage is Vdp, taking n data of the detecting point, and then operating as follows:
1. Firstly, the n voltage values of the detecting point are arranged in an ascending order or in a descending order, to obtain a data combination consisting of n voltage values that are rearranged;
2. Taking the value in the middle of the n data, i.e., the median value Vdp_mid:

If n is an even number, then:

$$Vdp\_mid = ( {Vdp}_{n / 2} + {Vdp}_{( n / 2 ) + 1} ) .$$

If n is an odd number, then:

$$Vdp\_mid = ( {Vdp}_{( n / 2 ) + 1} ) .$$

As can be seen from the above description, in the voltage filtering method for a detecting point provided in the embodiment of the present disclosure, only two filter modes are selected to filter the plurality of voltage data of the detecting point, such that on the basis of ensuring the validity of the voltage filtering results, the calculation amount and time cost is reduced to the maximum extent, so as to be able to effectively reduce circuit complexity and reduce energy waste.

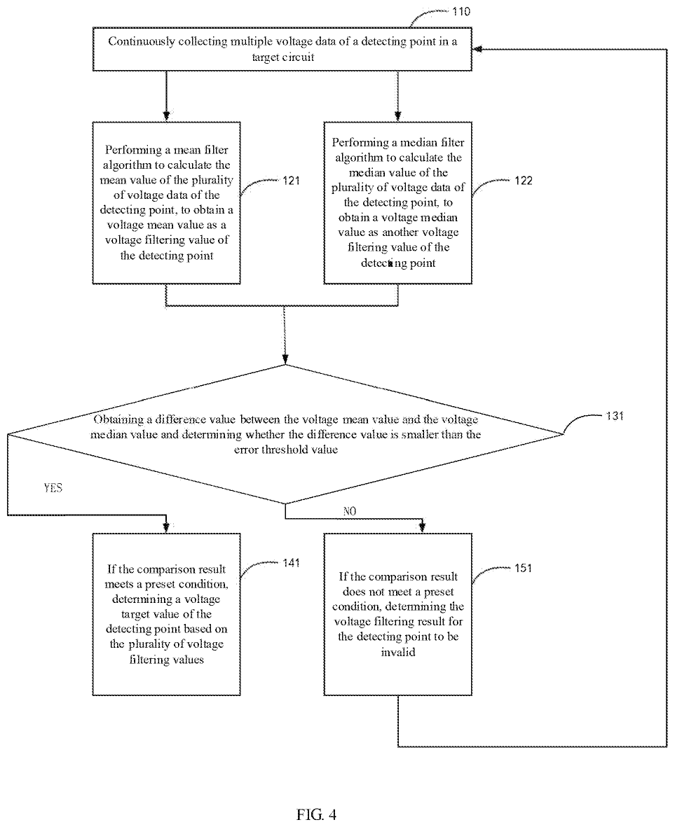

In order to further reduce circuit complexity and reduce energy waste, in an embodiment of the voltage filtering method for a detecting point provided in this disclosure, with reference to FIG. 4, the step 130 of the voltage filtering method for a detecting point may specifically include:

A step 131 of obtaining a difference value between the voltage mean value and the voltage median value and determining whether the difference value is smaller than the error threshold value, and if it is, executing the step 140 specifically including:

A step 141 of determining the voltage target value of the detecting point based on the voltage mean value and the voltage median value.

For example, after performing two filter algorithms provided in the steps 121 and 122, two values. Vdp_ave and Vdp_mid, are obtained, then subtraction is performed between the two values to obtain a difference value, and if the difference value is smaller than the error threshold value, determining the voltage target value of the detecting point based on the voltage mean value and the voltage median value: if the difference value is greater than or equal to the set error threshold value, returning to the step 110.

It can be understood that the manner of determining the voltage target value of the detecting point based on the voltage mean value and the voltage median value may include: calculating a mean value of the voltage mean value and the voltage median and determining the mean value as the voltage target value of the detecting point: or selecting any one of the voltage mean value and the voltage median value as the voltage target value of the detecting point.

As can be seen from the above description, in the voltage filtering method for a detecting point provided in the embodiment of the present disclosure, by determining the voltage target value of the detecting point based on the voltage mean value and the voltage median value, on the basis of ensuring the validity of the voltage filtering results, the calculation amount and time cost is further reduced, so as to be able to effectively reduce circuit complexity and reduce energy waste.

In order to solve the increasingly prominent energy crisis and environmental pollution problems, new energy vehicles have become the main direction of development in various countries. For a control guidance unit of a charging base of new energy vehicles, the effectiveness of detecting the switch state in the control guidance unit also determines the application reliability of the charging base of new energy vehicles. Accordingly, considering that a single filtering circuit and etc. are applied to the existing voltage filtering method for a detecting point to filter the ripple in the voltage, but this method cannot verify the effectiveness of voltage filtering, and thus cannot guarantee the accuracy of the switching state detection of the control guidance unit based on the filtered voltage, embodiments of the present disclosure provide a switch state detection method and switch state detecting apparatus which, based on the voltage filtering method for a detecting point mentioned in one or more of the above embodiments, obtains a voltage target value of a first detecting point after controlling a first switch to be closed, in which one end of the first switch is connected with a first resistor in the control guidance unit of a charging base, and the first detecting point is arranged at the other end of the first switch; determines whether the voltage target value of the first detecting point meets a first closing condition, and if so, determines that the first switch is currently in a closed state, thus effectively verifies the validity of the voltage filtering for the detecting point in the circuit, effectively ensures the reliability of the voltage filtering for the detecting point, effectively and reliably prevents the voltage jitter from causing the control misjudgment of the circuit, and is able to effectively improve the accuracy and reliability of the switch state detection in the control guidance unit of the charging base of new energy vehicles based on the filtered voltage, thereby effectively improving the work stability and reliability of the charging base of new energy vehicles.

The details are illustrated by the following multiple embodiments.

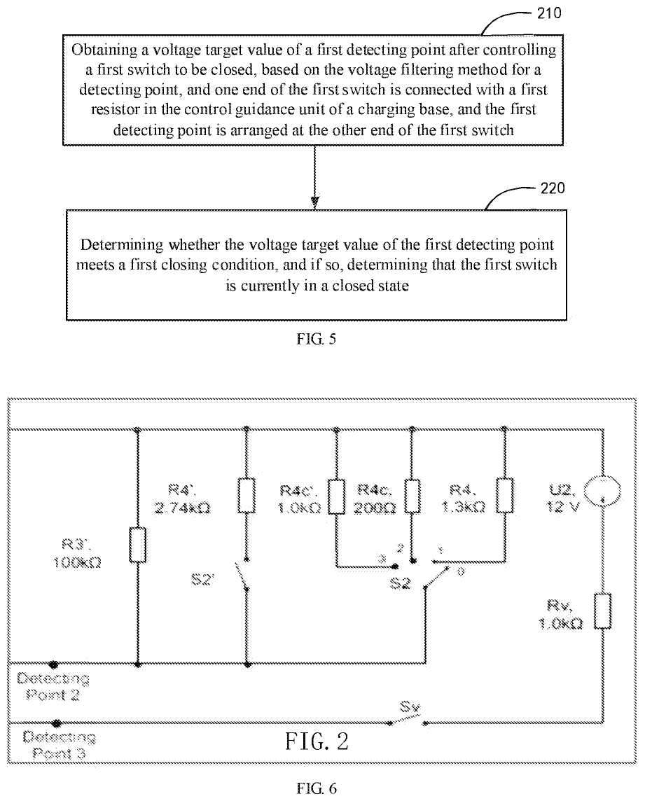

In order to solve that a single filtering circuit and etc. are applied to the existing voltage filtering method for a detecting point to filter the ripple in the voltage, but this method cannot verify the effectiveness of voltage filtering, and thus cannot guarantee the accuracy of the switching state detection of the control guidance unit based on the filtered voltage, in an embodiment of the switch state detection method provided in the present disclosure, with reference to FIG. 5, the switch state detection method specifically includes:

A step 210 of, obtaining a voltage target value of a first detecting point after controlling a first switch to be closed, based on a voltage filtering method for a detecting point, and one end of the first switch is connected with a first resistor in the control guidance unit of a charging base, and the first detecting point is arranged at the other end of the first switch.

It is understandable that the control guidance unit of the charging base is a specific implementation method of the target circuit. Therefore, in the step 210, the first detecting point is taken as the current detecting point in the voltage filtering method for a detecting point for filtering calculation, and for example, the steps 110 to 140 are applied to achieve the following:

Continuously collecting multiple voltage data of a first detecting point in the control guide unit of the charging base, respectively obtaining a plurality of voltage filtering values corresponding to the first detecting point by preforming a filter mode based on the multiple voltage data: comparing the plurality of voltage filtering values to obtain a corresponding comparison result, and if the comparison result satisfies the preset condition, determining a voltage target value Vdp3_last of the first detecting point based on the plurality of voltage filtering values.

In one or more embodiments of the present disclosure, the first detecting point is represented as DP3 and the first switch is represented as Sv.

A step 220 of determining whether the voltage target value of the first detecting point meets a first closing condition, and if so, determining that the first switch is currently in a closed state.

It can be understood that if it is determined in the step 220 that the voltage target value of the first detecting point does not meet a first closing condition, determining that the first switch fails to close and outputting an informing message indicating that the first switch fails to close. For example, the informing message may be displayed on the display that communicates with the switch state detection system, or the informing message is sent by a communication unit provided in the switch state detection system via a third-party server or itself to a client device held by the technician.

The client device held by the technician may include a smart phone, a tablet electronic device, a network set-top box, a portable computer, a desktop computer, a personal digital assistant (PDA), a vehicle-mounted device, a smart wearable device, etc. The smart wearable device may include smart glasses, a smart watch, a smart bracelet, etc. Thus, the efficiency of informing the message that the switch fails to close and the maintenance efficiency of the control guidance unit of the charging base by the technicians may be effectively improved.

The client device described above may have a communication module (that is, a communication unit), which communicates with a remote server to achieve data transmission with the server. The server may include a server on the side of the task scheduling center. In other implementation scenarios, a server of an intermediate platform may also be included, such as a server of a third-party server platform that communicates with the task scheduling center server. The server may include a single computer device, a server cluster composed of multiple servers, or a server structure of a distributed device.

Any suitable network protocol, including network protocols not yet developed at the filing date of the present disclosure, may be used to communicate between the server and the client device. The network protocol, for example, may include TCP/IP protocol, UDP/IP protocol, HTTP protocol, HTTPS protocol, etc. Of course, the network protocol may also include, for example, the Remote Procedure Call Protocol (RPC), the Representational State Transfer (REST) protocol, which are used over the above protocols, and etc.

As can be seen from the above description, the switch state detection method provided in the embodiment of the present disclosure effectively verifies the validity of the voltage filtering for the detecting point in the circuit, effectively ensures the reliability of the voltage filtering for the detecting point, effectively and reliably prevents the voltage jitter from causing the control misjudgment of the circuit, and is able to effectively improve the accuracy and reliability of the switch state detection in the control guidance unit of the charging base of new energy vehicles based on the filtered voltage, thereby effectively improving the work stability and reliability of the charging base of new energy vehicles.

In order to further improve the application pertinence of the switch state detection method, in an embodiment of the switch state detection method of the present disclosure, the charging base is a compatible new energy vehicle charging base configured to compatibility with multiple charging protocols.

That is to say, the control guidance unit referred to in one or more embodiments of the present disclosure may be a control guidance unit specifically for a compatible new energy vehicle charging base compatible with multiple charging protocols.

It can be understood that in one specific example of the control guidance unit, with reference to FIG. 6, the control guidance unit may include: a first switch Sv, a first resistor Ry, a power supply U2, a second switch S2′, a second resistor R4′ and a selection switch S2. One end of the first switch Sv is connected with the first resistor Ry in the control guidance unit of the charging base of the compatible new energy vehicle, and the first detecting point DP3 (the Detecting Point 3 in FIG. 6) is arranged at the other end of the first switch Sv, the first resistor Rv is connected in series with the power supply U2 and forms a branch. One end of the second switch S2′ is connected in series with the second resistor R4′ in the control guidance unit to form a first branch, the first branch is connected in parallel with the branch where the first resistor Ry is located, and the first branch is also connected in parallel with the branch where the third resistor R3′ is located. The control points 1 to 3 corresponding to the charging protocols corresponding to one end of the selection switch S2 are respectively connected with a resistor (i.e., a resistor R4c′, a resistor R4c and a resistor R4), and the other end of the selection switch S2 is connected with the branch where the second detecting point DP2 (the Detecting Point 2 in FIG. 6) is located, and the branch where the second detecting point DP2 is located is also connected with the other end of the second switch S2′. The selection switch S2 is arranged on a second branch, and the second branch is respectively connected in parallel with the branch where the first resistor Ry is located and the first branch.

It can be understood that the first switch Sv is a connection state detection switch for detecting the connection state, the second switch S2′ is a charge control switch for performing charge control, and the selection switch S2 is a protocol compatible switch for performing protocol compatibility:

In order to further improve the accuracy of the first switch state detection, in an embodiment of the switch state detection method of the present disclosure, the first closing condition of the switch state detection method specifically includes the following contents:

The voltage target value of the first detecting point obtained after the first switch is controlled to be closed is not equal to the voltage target value of the first detecting point obtained in advance before the first switch is controlled to be closed, and the voltage target value of the first detecting point obtained after the first switch is controlled to be closed is within the voltage range corresponding to either of the charging protocols.

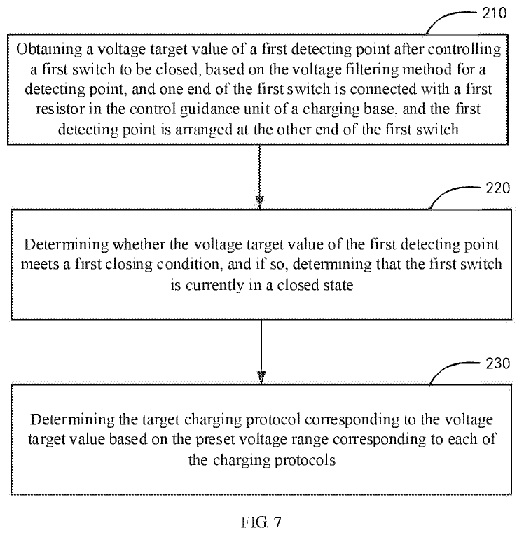

To provide a way to identify the charging protocol, in an embodiment of the switch state detection method of the present disclosure, with reference to FIG. 7, subsequent to the step 220, the switch state detection method further specifically includes:

A step 230 of determining a target charging protocol corresponding to the voltage target value based on the preset voltage range corresponding to each of the charging protocols.

From the above description, it can be seen that the switch state detection method provided by the embodiment of the present disclosure improves the reliability of closing the selection switch, meets the compatibility requirements of the compatible new energy vehicle charging base, and further improves the application reliability and stability of the compatible new energy vehicle charging base.

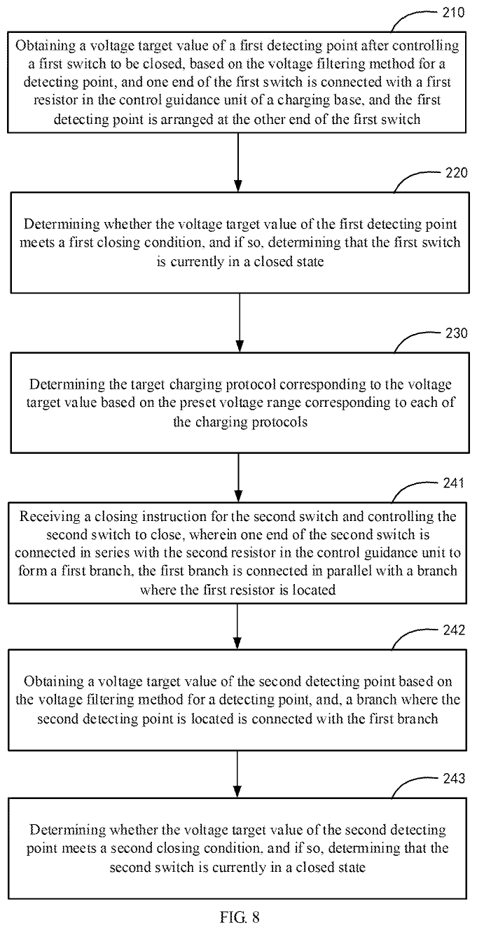

In order to improve the comprehensiveness and effectiveness of the switch state detection, in an embodiment of the switch state detection method of the present disclosure, with reference to FIG. 8, subsequent to the step 230, the switch state detection method further specifically includes:
A step 241 of receiving a closing instruction for the second switch and controlling the second switch to close, and one end of the second switch is connected in series with the second resistor in the control guidance unit to form a first branch, the first branch is connected in parallel with a branch where the first resistor is located;
A step 242 of obtaining a voltage target value of the second detecting point based on the voltage filtering method for a detecting point, and, a branch where the second detecting point is located is connected with the first branch; and
A step 243 of determining whether the voltage target value of the second detecting point meets a second closing condition, and if so, determining that the second switch is currently in a closed state.

In order to further improve the accuracy of the second switch state detection, in an embodiment of the switch state detection method of the present disclosure, the second closing condition of the switch state detection method specifically includes the following content:
the voltage target value of the second detecting point obtained after the second switch is controlled to be closed is not equal to the voltage target value of the second detecting point obtained in advance before the second switch is controlled to be closed.

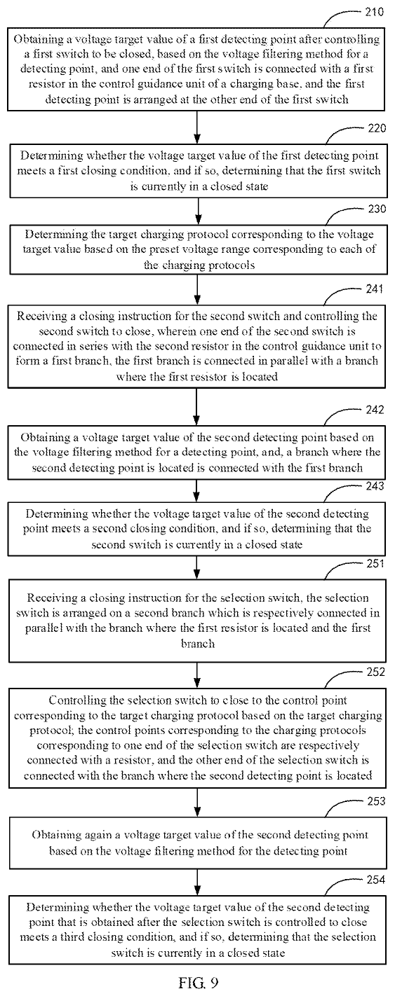

In order to improve the comprehensiveness and effectiveness of the selection switch state detection, in an embodiment of the switch state detection method of the present disclosure, with reference to FIG. 9, subsequent to the step 243, the switch state detection method further specifically includes:
A step 251 of receiving a closing instruction for a selection switch, and the selection switch is arranged on a second branch which is respectively connected in parallel with the branch where the first resistor is located and the first branch; and
A step 252 of controlling the selection switch to close to the control point corresponding to the target charging protocol based on the target charging protocol; and the control points corresponding to the charging protocols corresponding to one end of the selection switch are respectively connected with a resistor, and the other end of the selection switch is connected with the branch where the second detecting point is located;
A step 253 of obtaining again a voltage target value of the second detecting point based on the voltage filtering method for a detecting point; and
A step 254 of determining whether the voltage target value of the second detecting point that is obtained after the selection switch is controlled to close meets a third closing condition, and if so, determining that the selection switch is currently in a closed state.

From the above description, it can be seen that the switch state detection method provided by the embodiment of the present disclosure improves the reliability of closing the selection switch, meets the compatibility requirements of the compatible new energy vehicle charging base, and further improves the application reliability and stability of the compatible new energy vehicle charging base.

In order to further improve the accuracy of the selection switch state detection, in an embodiment of the switch state detection method of the present disclosure, the third closing condition of the switch state detection method specifically includes the following content:
the voltage target value of the second detecting point obtained after the selection switch is controlled to be closed is not equal to the voltage target value of the second detecting point obtained in advance before the selection switch is controlled to be closed.

On this basis, aiming at the ChaoJi charging system, which solves a series of defects and problems in the existing charging system and provide the world with a unified, safe, reliable and low-cost charging system solution, each of the charging protocols referred to in one or more embodiments of the present disclosure may include at least the ChaoJi charging standard, the GB (national standard of China) 2015 charging standard and the CHAdeMO (Charge de move: the fast-charging standard of electric vehicle in Japan) charging standard. That is to say, the compatible new energy vehicle charging base configured to compatibility with multiple charging protocols can be compatible with the ChaoJi charging standard, the GB 2015 charging standard and the CHAdeMO charging standard.

Based on this, in the switch state detection method, the voltage range corresponding to the ChaoJi charging standard is (5.64V, 6.36V).

The voltage range corresponding to the GB 2015 charging standard is (7.54V, 8.45V).

The voltage range corresponding to the CHAdeMO charging standard is (1.86V, 2.14V).

Then a specific example that the voltage target value of the first detecting point which is obtained after the first switch is controlled to close, referred to in the first closing condition, is within the voltage range corresponding to either of the charging protocols is as follows:

the voltage target value Vdp3 of the first detecting point DP3 is in any range of 5.64V<Vdp3<6.36V (ChaoJi), 7.54V<Vdp3<8.45V (GB2015), 1.86V<Vdp3<2.14V (CHAdeMO).

Correspondingly, the control point 1 corresponding to one end of the selection switch S2 in FIG. 6 is the control point corresponding to the CHAdeMO charging standard: the control point 3 is the control point corresponding to the GB 2015 charging standard: the control point 2 is the control point corresponding to the CHAdeMO charging standard.

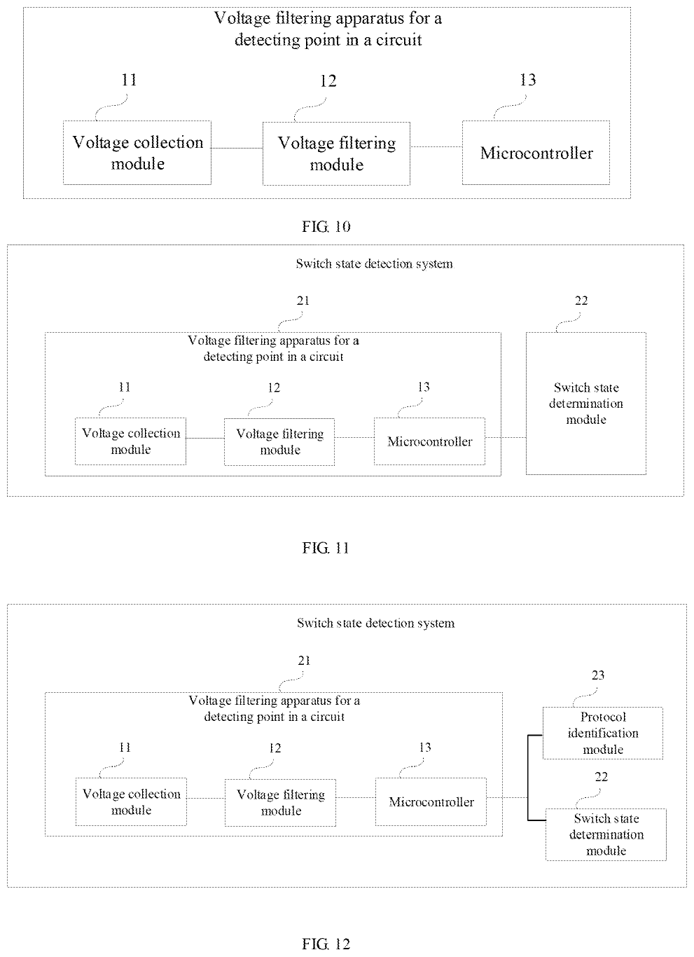

In order to solve the problems that the existing voltage filtering method for a detecting point cannot verify the effectiveness of voltage filtering, and thus cannot guarantee the accuracy of subsequent control or detection based on the filtered voltage, an embodiment of the present disclosure provides a voltage filtering apparatus for a detecting point in a circuit for realizing any or all of the contents of the voltage filtering method for a detecting point in a circuit, with reference to FIG. 10, the voltage filtering apparatus for a detecting point in a circuit specifically includes:

A voltage collection module 11 configured to continuously collect multiple voltage data of a detecting point in a target circuit.

In the voltage collection module 11, the continuous collection refers to collecting the data a preset number of times during a preset period, such as 10 times in 0.3 S, and then 10 voltage data Vdp₁ to Vdp₁₀ for a detecting point are obtained.

It can be understood that the voltage data refers to a digital signal, and the collection process of the digital signal is: collecting a voltage analog signal of a collection point in a target circuit: then converting the voltage analog signal to a digital signal to obtain a digital signal for subsequent filtering processing.

A voltage filtering module 12 configured to respectively obtain a plurality of voltage filtering values corresponding to the detecting point by preforming filter modes based on the multiple voltage data.

In the voltage filtering module 12, two or more filter modes may be selected to process the plurality of voltage data respectively to obtain the voltage filtering values corresponding to the detecting point, and the number of the voltage filtering values is equal to the selected filter modes. For example, if four filter modes A, B, C, and D are selected, the filtering results corresponding to the four filter modes are obtained, namely, the voltage filtering values A1, B1, C1, and D1. In a specific example, the filter modes may be selected as at least two of mean filter, median filter, post-interpolation filter, post-dimensionality-reduction filter and neighborhood average filter modes.

A microcontroller 13 configured to compare the plurality of voltage filtering values, and if the corresponding comparison result meets a preset condition, determine a voltage target value of the detecting point based on the plurality of voltage filtering values.

In the microcontroller 13, the manner of comparing the plurality of voltage filtering values may include obtaining a difference value between the maximum value and the minimum value of the plurality of voltage filtering values; and taking the difference value as a comparison result to determine whether the difference value is smaller than a threshold value such as a preset error threshold value; and if it is, determining the voltage target value of the detecting point based on the plurality of voltage filtering values.

It can be understood that the manner of determining the voltage target value of the detecting point based on the plurality of voltage filtering values may include: calculating a mean value of the plurality of voltage filtering values and determining the mean value as a voltage target value of the detecting point: or selecting a median value of the plurality of voltage filtering values, and determining the median value as the voltage target value of the detecting point: or selecting any one of the plurality of voltage filtering values as the voltage target value of the detecting point.

The embodiment of the voltage filtering apparatus for a detecting point in a circuit provided in the present disclosure may specifically be used to execute the processing flow of the embodiment of the voltage filtering method for a detecting point in the above embodiment, and the function thereof will not be repeated here and may be found by referring to the detailed description of the above embodiment of the voltage filtering method for a detecting point.

As can be seen from the above description, the voltage filtering apparatus for a detecting point provided in the embodiment of the present disclosure effectively verifies the validity of the voltage filtering for the detecting point in the circuit, effectively ensures the reliability of the voltage filtering for the detecting point, and effectively and reliably prevents the voltage jitter from causing the control misjudgment of the circuit, thereby effectively improving the accuracy and reliability of subsequent control or detection based on the filtered voltage. Especially for a control guidance unit and etc. of a charging base of new energy vehicles, the accuracy of detecting the switch state in the control guidance unit based on the filtered voltage is improved, thereby effectively improving the work stability and reliability of the control guidance unit of the charging base of new energy vehicles.

In order to provide a reliable processing method when it is verified that the voltage filtering result for the detecting point are invalid or unreliable, in an embodiment of the voltage filtering apparatus for a detecting point provided by the present disclosure, the microcontroller 13 in the detection point voltage filter device is also configured to perform the following operation:

If the comparison result does not meet the preset condition, controlling the voltage collection module to continuously collect multiple voltage data of the detecting point again and controlling the voltage filtering module to obtain a plurality of voltage filtering values corresponding to the detecting point again, until a comparison result obtained by the microcontroller again meets the preset condition and the voltage target value of the detecting point is determined.

As can be seen from the above description, by the voltage filtering apparatus for a detecting point provided in the embodiment of the present disclosure, a reliable processing method is provided when it is verified that the voltage filtering result for the detecting point in the circuit are invalid or unreliable, to further ensure the reliability of voltage filtering for the detecting point, thus the method effectively and reliably prevents the voltage jitter from causing the control misjudgment of the circuit, and effectively improves the widely applicable property of the voltage filtering process for the detecting point.

In order to reduce circuit complexity and reduce energy waste, in an embodiment of the voltage filtering apparatus for a detecting point provided in this disclosure, the voltage filtering module 12 in the voltage filtering apparatus for a detecting point may specifically include:
A mean filter unit configured to perform a mean filter algorithm to calculate the mean value of the plurality of voltage data of the detecting point, to obtain a voltage mean value as a voltage filtering value of the detecting point; and
A median filter unit configured to perform a median filter algorithm to calculate the median value of the plurality of voltage data of the detecting point, to obtain a voltage median value as another voltage filtering value of the detecting point.

As can be seen from the above description, in the voltage filtering apparatus for a detecting point provided in the embodiment of the present disclosure, only two filter modes are selected to filter the plurality of voltage data of the detecting point, such that on the basis of ensuring the validity of the voltage filtering results, the calculation amount and time cost is reduced to the maximum extent, so as to be able to effectively reduce circuit complexity and reduce energy waste.

In order to further reduce circuit complexity and reduce energy waste, in an embodiment of the voltage filtering apparatus for a detecting point provided in this disclosure, the microcontroller 13 in the voltage filtering apparatus for a detecting point may specifically include:

An error determination unit configures to obtain a difference value between the voltage mean value and the voltage median value and determining whether the difference value is smaller than the error threshold value, and if it is, determine the voltage target value of the detecting point based on the voltage mean value and the voltage median value.

As can be seen from the above description, in the voltage filtering apparatus for a detecting point provided in the embodiment of the present disclosure, by determining the voltage target value of the detecting point based on the voltage mean value and the voltage median value, on the basis of ensuring the validity of the voltage filtering results, the calculation amount and time cost is further reduced, so as to be able to effectively reduce circuit complexity and reduce energy waste.

In order to solve that a single filtering circuit and etc. are applied to the existing voltage filtering method for a detecting point to filter the ripple in the voltage, but this method cannot verify the effectiveness of voltage filtering, and thus cannot guarantee the accuracy of the switching state detection of the control guidance unit based on the filtered voltage, the present disclosure provides an embodiment of a switch state detection system for implementing all or part of the switch state detection method, with reference to FIG. 11, the switch state detection system specifically includes:
A voltage filtering apparatus 21 for a detecting point configured to, obtain a voltage target value of a first detecting point after controlling a first switch to be closed, based on a voltage filtering method for a detecting point, and one end of the first switch is connected with a first resistor in the control guidance unit of a charging base, and the first detecting point is arranged at the other end of the first switch; and
A switch state determination module 22 configured to determine whether the voltage target value of the first detecting point meets a first closing condition, and if so, determine that the first switch is currently in a closed state.

It can be understood that if it is determined by the switch state determination module 22 that the voltage target value of the first detecting point does not meet a first closing condition, determining that the first switch fails to close and outputting an informing message indicating that the first switch fails to close. For example, the informing message may be displayed on the display that communicates with the switch state detection system, or the informing message is sent by a communication unit provided in the switch state detection system via a third-party server or itself to a client device held by the technician.

The embodiment of the switch state detection system provided in the present disclosure may specifically be used to execute the processing flow of the embodiment of the switch state detection method in the above embodiment, and the function thereof will not be repeated here and can be found by referring to the detailed description of the above embodiment of the switch state detection method.

As can be seen from the above description, the switch state detection system provided in the embodiment of the present disclosure effectively verifies the validity of the voltage filtering for the detecting point in the circuit, effectively ensures the reliability of the voltage filtering for the detecting point, effectively and reliably prevents the voltage jitter from causing the control misjudgment of the circuit, and is able to effectively improve the accuracy and reliability of the switch state detection in the control guidance unit of the charging base of new energy vehicles based on the filtered voltage, thereby effectively improving the work stability and reliability of the charging base of new energy vehicles.

In order to further improve the application pertinence of the switch state detection method, in an embodiment of the switch state detection system of the present disclosure, the charging base is a compatible new energy vehicle charging base configured to compatibility with multiple charging protocols.

In order to further improve the accuracy of the first switch state detection, in an embodiment of the switch state detection system of the present disclosure, the first closing condition of the switch state detection system specifically includes the following contents:

The voltage target value of the first detecting point obtained after the first switch is controlled to be closed is not equal to the voltage target value of the first detecting point obtained in advance before the first switch is controlled to be closed, and the voltage target value of the first detecting point obtained after the first switch is controlled to be closed is within the voltage range corresponding to either of the charging protocols.

To provide a method to identify the charging protocol, in an embodiment of the switch state detection system of the present disclosure, with reference to FIG. 12, the switch state detection system further specifically includes:

A protocol identification module 23 configured to determine a target charging protocol corresponding to the voltage target value based on a preset voltage range corresponding to each of the charging protocols.

From the above description, it can be seen that the switch state detection system provided by the embodiment of the present disclosure improves the reliability of closing the selection switch, meets the compatibility requirements of the compatible new energy vehicle charging base, and further improves the application reliability and stability of the compatible new energy vehicle charging base.

In order to improve the comprehensiveness and effectiveness of the switch state detection, in an embodiment of the switch state detection system of the present disclosure, the voltage filtering apparatus for a detecting point in a circuit of the switch state detection system includes a voltage collection module 11, a voltage filtering module 12 and a microcontroller 13 that are connected in sequence.

The microcontroller 13 is further configured to receive a closing instruction for a second switch and control the second switch to close, and one end of the second switch is connected in series with the second resistor in the control guidance unit to form a first branch, the first branch is connected in parallel with the branch where the first resistor is located.

The voltage collection module 11, the voltage filtering module 12 and the microcontroller 13 that are connected in sequence are further configured to obtain a voltage target value of the second detecting point based on the voltage filtering method for a detecting point, and, the branch where the second detecting point is located is connected with the first branch.

The switch state determination module 22 is further configured to determine whether the voltage target value of the second detecting point meets a second closing condition, and if so, determine that the second switch is currently in a closed state.

In order to further improve the accuracy of the second switch state detection, in an embodiment of the switch state detection system of the present disclosure, the second closing condition of the switch state detection method specifically includes the following content:

The voltage target value of the second detecting point obtained after the second switch is controlled to be closed is not equal to the voltage target value of the second detecting point obtained in advance before the second switch is controlled to be closed.

In order to improve the comprehensiveness and effectiveness of the selection switch state detection, in an embodiment of the switch state detection system of the present disclosure, the microcontroller 13 in the switch state detection system is further configured to receive a closing instruction for the selection switch, and the selection switch is arranged on a second branch, and the second branch is respectively connected in parallel with the branch where the first resistor is located and the first branch; and

Control the selection switch to close to the control point corresponding to the target charging protocol based on the target charging protocol; and the control points corresponding to the charging protocols corresponding to one end of the selection switch are respectively connected with a resistor, and the other end of the selection switch is connected with the branch where the second detecting point is located.

The voltage collection module 11, the voltage filtering module 12 and the microcontroller 13 that are connected in sequence are further configured to obtain again the voltage target value of the second detecting point based on the voltage filtering method for a detecting point.

The switch state determination module 14 is further configured to determine whether the voltage target value of the second detecting point that is obtained after the selection switch is controlled to close meets a third closing condition, and if so, determine that the selection switch is currently in a closed state.

From the above description, it can be seen that the switch state detection system provided by the embodiment of the present disclosure improves the reliability of closing the selection switch, meets the compatibility requirements of the compatible new energy vehicle charging base, and further improves the application reliability and stability of the compatible new energy vehicle charging base.

In order to further improve the accuracy of the selection switch state detection, in an embodiment of the switch state detection system of the present disclosure, the third closing condition of the switch state detection system specifically includes the following contents:

The voltage target value of the second detecting point obtained after the selection switch is controlled to be closed is not equal to the voltage target value of the second detecting point obtained in advance before the selection switch is controlled to be closed.

On this basis, each of the charging protocols may include at least the ChaoJi charging standard, the GB 2015 charging standard and the CHAdeMO (Charge de move: the fast-charging standard of electric vehicle in Japan) charging standard. That is to say, the compatible new energy vehicle charging base configured to compatibility with multiple charging protocols can be compatible with the ChaoJi charging standard, the GB 2015 charging standard and the CHAdeMO charging standard.

Based on this, in the switch state detection system, the voltage range corresponding to the ChaoJi charging standard is (5.64V, 6.36V).

The voltage range corresponding to the GB 2015 charging standard is (7.54V, 8.45V).

The voltage range corresponding to the CHAdeMO charging standard is (1.86V, 2.14V).

In order to further illustrate the technical solution, the present disclosure further provides a specific application example of implementing the switch state detection method by using the switch state detection system, for a charging base compatible with ChaoJi (ChaoJi super charging standard), GB 2015, CHAdeMO (Charge de move: the fast-charging standard of electric vehicle in Japan), in order to reduce circuit complexity and reduce energy waste, the application example of the present disclosure provides a logical algorithm to determine the switch state based on voltage of the detecting point (DP (including DP2\DP3)). Specific functions are as follows:

Referring to FIG. 12, the switch state detection system includes a voltage collection module 11, a voltage filtering module 12, a switch state determination module 22, a protocol identification module 23 and a microcontroller 13, which are described specifically as below:
(1) The voltage collection module 11 is configured to collect the voltage of the DP, and convert the voltage analog signal of the DP to a digital signal.
(2) The voltage filtering module 12 configured to filter the obtained digital signal of the obtained DP voltage to prevent the system from misjudgment caused by voltage jitter.
(3) The switch state determination module 22 configured to determine the switch state (open (turn off) or close (turn on)) based on the change of DP2 point voltage.
(4) The protocol identification module 23 configured to determine the voltage of the DP3 point by the microcontroller, identify the current state as the ChaoJi standard when the DP3 voltage is higher than 5.64 and lower than 6.36; identify the current state as the (GB 2015) standard when the DP3 voltage is higher than 7.54 and lower than 8.45; and identify the current state as the CHAdeMO standard when the DP3 voltage is higher than 1.86 and lower than 2.14.
(5) The microcontroller 13 configured to obtain the voltage value via the DP point input to the voltage filtering algorithm module, obtain the true value of the DP point voltage, and perform logical operations to determine the state of the switch.

On the basis of FIG. 12, the switch state detection system may further include a switch control unit that controls the open and close of the switch by the microcontroller 13.

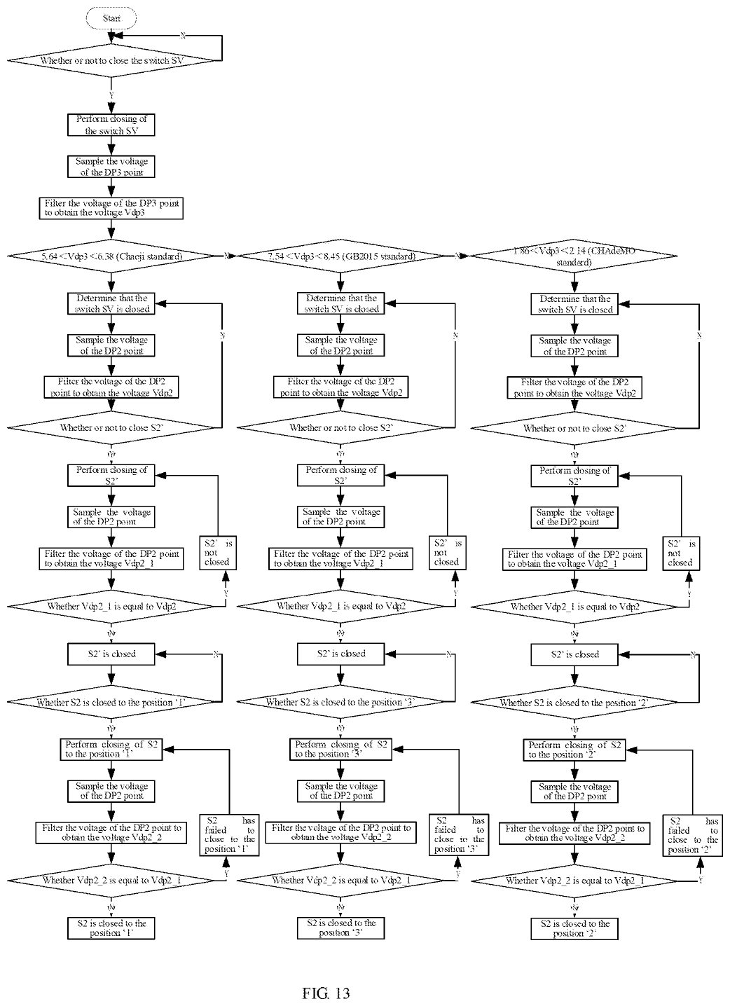

Based on the switch state detection system described above, the application example of the present disclosure further provides a switch state detection method that is implemented based on the switch state detection system, with reference to FIG. 13, specifically including:

S1: waiting for the CCU (on-board charge controller) to send a closing Sv command after the device is powered on. The CCU sends the closing command, the microcontroller unit controls the Sv to close, and the switch control unit performs Sv closing.

S2: measuring the voltage value of the DP3 point and filtering the DP3 voltage to obtain a stable voltage value: the microcontroller controls to read the current Vdp3_last voltage that is recorded before the Sv is closed, and the microcontroller reads the voltage is Vdp3 when the Sv is controlled to be closed, for example, if Vdp3_last is equal to Vdp3 or is not within in the range of 5.64V<Vdp3<6.36V (Chaoji), 7.54V<Vdp3<8.45V (GB2015), 1.86V<Vdp3<2.14V (CHAdeMO), it is determined that Sv has failed to close and Sv is open.

S3: if the DP3 voltage value is within the above range, it is determined that Sv has succeeded to close, and the current standard to be performed are determined based on the voltage value as described above.

S4: when the standard is determined, waiting for the CCU to send a closing command for S2′, CCU sends a command to close S2′, measures the DP2 voltage, filters and records the current DP2 voltage value.

The microcontroller controls S2′ to be closed, the switch controller performs closing of S2′, and thereafter measures the DP2 voltage and performs filtering. If the DP2 voltage after S2′ is controlled to be closed is not equal to that before S2′ is controlled to be closed, it is determined that S2′ is closed: otherwise, it is determined that S2′ has failed to be closed.

S5: after S2′ is closed, waiting for a command to close S2 from CCU, CCU sends a command to close S2, measures the DP2 voltage and performs filtering: the microcontroller controls the position where S2 is closed based on different protocols, the microcontroller controls to close S2, and the switch controller performing closing of S2. The DP2 voltage is measured and filtering is performed. If the DP2 voltage after S2 is controlled to be closed is not equal to that before S2′ is controlled to be closed, it is determined that S2 is closed: otherwise, it is determined that S2 has failed to be closed.

And, filter algorithm involved in S2 is as follows:

In order to ensure the accuracy of the data, two different filter algorithms are used, and then the output values thereof are compared. If the difference value between the values outputted by the two methods is smaller than the set error threshold value, it is determined that the data is correct this time.

### (1) Mean Algorithm

Assuming that the voltage of DP point (DP2, DP3) is Vdp, taking n data of DP point, and the sum of n data is Vdp_sum, the average value of n data is Vdp_ave

$$Vdp\_sum = {Vdp}_{1} + {Vdp}_{2} + {Vdp}_{3} + … + {Vdp}_{n - 1} + {Vdp}_{n} Vdp\_ave = sum / n ;$$

### (2) Median Filter Algorithm

Assuming that the voltage of DP point (DP2, DP3) is Vdp, and taking n data of DP point.
1. Firstly, the n voltage values of the DP point are arranged in an ascending order or in a descending order, to obtain a new combination of n data;
2. Taking the middle value of N data;
3. The median value is Vdp mid:

If N is an even number, then Vdp_mid=(Vdp_{n/2}+Vdp_{(n/2)+1})/2

If N is an odd number, then Vdp_mid=(Vdp_{(n/2)+1})

3.6.4 After performing two filter algorithms, two values, Vdp_ave and Vdp_mid, are obtained, and then subtraction is performed between the two values: if the difference value is greater than the set threshold value, the data is determined to be incorrect and the set of data is discarded, and the microcontroller re-obtains n data from the filtering module for the above algorithm. Re-collection is to collect a set of n data of the DP points and perform filtering calculation; if the data is wrong, a set of new n data is re-collected.

In terms of hardware, in order to solve that the existing voltage filtering method for a detecting point cannot verify the effectiveness of voltage filtering, and thus cannot guarantee the accuracy of subsequent control or detection based on the filtered voltage, the present disclosure provides an embodiment of an electronic device for implementing all or part of the voltage filtering method for a detecting point in a circuit or the switch state detection method, and the electronic device specifically includes the following:

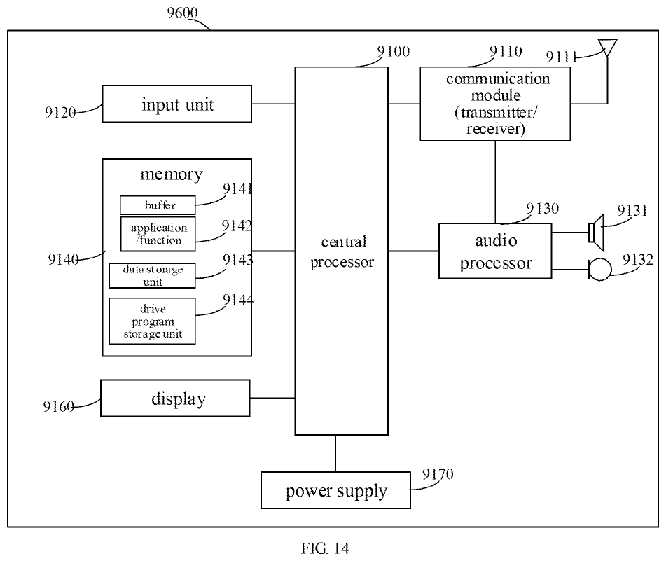

FIG. 14 is a schematic block diagram of system configuration of an electronic device 9600 according to an embodiment of the present disclosure. As shown in FIG. 14, the electronic device 9600 may include a central processor 9100 and a memory 9140; the memory 9140 is coupled to the central processor 9100. It is worth noting that FIG. 14 is exemplary: other types of structures may also be used in addition to or instead of the structure to implement telecommunications functions or other functions.

In an embodiment, the voltage filtering function for a detecting point in a circuit may be integrated into the central processor. The central processor may be configured to perform the following control of:

A step 110 of continuously collecting multiple voltage data of a detecting point in a target circuit:

A step 120 of respectively obtaining a plurality of voltage filtering values corresponding to the detecting point by preforming filter modes based on the multiple voltage data:

A step 130 of comparing the plurality of voltage filtering values to obtain a corresponding comparison result; and

A step 140 of, if the comparison result meets a preset condition, determining a voltage target value of the detecting point based on the plurality of voltage filtering values.

As can be seen from the above description, the electronic device for implementing the voltage filtering method for a detecting point in a circuit provided in the embodiment of the present disclosure effectively verifies the validity of the voltage filtering for the detecting point in the circuit, effectively ensures the reliability of the voltage filtering for the detecting point, effectively and reliably prevents the voltage jitter from causing the control misjudgment of the circuit, thereby effectively improving the accuracy and reliability of subsequent control or detection based on the filtered voltage. Especially for a control guidance unit and etc. of a charging base of new energy vehicles, the accuracy of detecting the switch state in the control guidance unit based on the filtered voltage is improved, thereby effectively improving the work stability and reliability of the control guidance unit of the charging base of new energy vehicles.

Alternatively, in another embodiment, the switch state detection function may be integrated into the central processor. The central processor may be configured to perform the following control of:
A step 210 of, obtaining a voltage target value of a first detecting point after controlling a first switch to be closed, based on the voltage filtering method for a detecting point, and one end of the first switch is connected with a first resistor in the control guidance unit of a charging base, and the first detecting point is arranged at the other end of the first switch; and
A step 220 of determining whether the voltage target value of the first detecting point meets a first closing condition, and if so, determining that the first switch is currently in a closed state.

As can be seen from the above description, the electronic device for implementing the switch state detection method provided in the embodiment of the present disclosure effectively verifies the validity of the voltage filtering for the detecting point in the circuit, effectively ensures the reliability of the voltage filtering for the detecting point, effectively and reliably prevents the voltage jitter from causing the control misjudgment of the circuit, and is able to effectively improve the accuracy and reliability of the switch state detection in the control guidance unit of the charging base of new energy vehicles based on the filtered voltage, thereby effectively improving the work stability and reliability of the charging base of new energy vehicles.

In another embodiment, the voltage filtering apparatus for a detecting point in a circuit or the switch state detection apparatus may be configured separately from the central processor 9100. For example, the voltage filtering apparatus for a detecting point in a circuit or the switch state detection apparatus may be configured as a chip connected to the central processor 9100, and the voltage filtering function for a detecting point in a circuit or the switch state detection function may be implemented by the control of the central processor.

As shown in FIG. 14, the electronic device 9600 may further include a communication module 9110, an input unit 9120, an audio processor 9130, a display 9160, and a power supply 9170. It is worth noting that the electronic device 9600 is not necessarily required to include all of the components shown in FIG. 14; in addition, the electronic device 9600 may further include components not shown in FIG. 14, with reference to the prior art.

As shown in FIG. 14, the central processor 9100, sometimes referred to as a controller or an operational control, may include a microprocessor or other processor apparatuses and/or logic apparatuses, the central processor 9100 receives inputs and controls operation of the components of the electronic device 9600.

Where, the memory 9140 may be, for example, one or more of a buffer, a flash memory, a hard drive, a removable media, a volatile memory, a non-volatile memory, or other suitable apparatuses. The above-described failure-related information may be stored, and in addition, a program for executing the relevant information may be stored. And the central processor 9100 may execute the program stored in the memory 9140 to implement information storage or processing and the like.

The input unit 9120 provides an input to the central processor 9100. The input unit 9120 is, for example, a key or a touch input apparatus. The power supply 9170 is configured to provide electric power to the electronic device 9600. The display 9160 is configured to display objects to be displayed, such as images and text, and the like. The display may be, for example, an LCD display, but is not limited thereto.

The memory 9140 may be a solid-state memory such as read only memory (ROM), random access memory (RAM), SIM card, or the like. The memory may also be such a memory that it saves information even when power is off, on which data can be selectively erased and more data is set, and an example of which is sometimes referred to as an EPROM or the like. The memory 9140 may also be some other types of apparatuses. The memory 9140 includes a buffer memory 9141 (sometimes referred to as a buffer). The memory 9140 may include an application/function storage unit 9142 configured to store a flow for performing operation of an electronic device 9600 by the central processor 9100, or application programs and function programs.

The memory 9140 may also include a data storage unit 9143 for storing data, such as contacts, digital data, pictures, sounds, and/or any other data used by the electronic device. A drive program storage unit 9144 of the memory 9140 may include various drive programs of the electronic device for communication functions and/or for executing other functions of the electronic device, such as a messaging application, an address book application, and the like.

The communication module 9110 is a transmitter/receiver 9110 that transmits and receives signals via an antenna 9111. The communication module (transmitter/receiver) 9110 is coupled to the central processor 9100 to provide input signals and to receive output signals, which may be the same as in the case of conventional mobile communication terminals.

Based on different communication technologies, a plurality of communication modules 9110, such as a cellular network module, a Bluetooth module, and/or a wireless local area network module and the like may be provided in the same electronic device. The communication module (transmitter/receiver) 9110 is also coupled to a speaker 9131 and a microphone 9132 via an audio processor 9130 to provide an audio output via the speaker 9131, and to receive an audio input from the microphone 9132, thereby implementing the usual telecommunications functions. The audio processor 9130 may include any suitable buffer, decoder, amplifier, or the like. In addition, the audio processor 9130 is also coupled to the central processor 9100 so that sound can be recorded on the local machine by the microphone 9132, and the sound stored on the local machine can be played by the speaker 9131.

The embodiment of the present disclosure further provides a computer-readable storage media capable of implementing all steps of the voltage filtering method for a detecting point in a circuit or the switch state detection method in the above embodiments, the computer-readable storage media stores a computer program which, when being executed by a processor, implements all steps of the voltage filtering method for a detecting point in a circuit or the switch state detection method in the above embodiments, and for example, the processor executes the computer program to implement the following steps:
A step 110 of continuously collecting multiple voltage data of a detecting point in a target circuit;
A step 120 of respectively obtaining a plurality of voltage filtering values corresponding to the detecting point by preforming filter modes based on the multiple voltage data;
A step 130 of comparing the plurality of voltage filtering values to obtain a corresponding comparison result; and
A step 140 of, if the comparison result meets a preset condition, determining a voltage target value of the detecting point based on the plurality of voltage filtering values.

As can be seen from the above description, the computer-readable storage media for implementing the voltage filtering method for a detecting point in a circuit provided in the embodiment of the present disclosure effectively verifies the validity of the voltage filtering for the detecting point in the circuit, effectively ensures the reliability of the voltage filtering for the detecting point, effectively and reliably prevents the voltage jitter from causing the control misjudgment of the circuit, thereby effectively improving the accuracy and reliability of subsequent control or detection based on the filtered voltage. Especially for a control guidance unit and etc. of a charging base of new energy vehicles, the accuracy of detecting the switch state in the control guidance unit based on the filtered voltage is improved, thereby effectively improving the work stability and reliability of the control guidance unit of the charging base of new energy vehicles.

Alternatively, the processor executes the computer program to implement the following steps:
A step 210 of, obtaining a voltage target value of a first detecting point after controlling a first switch to be closed, based on the voltage filtering method for a detecting point, and one end of the first switch is connected with a first resistor in the control guidance unit of a charging base, and the first detecting point is arranged at the other end of the first switch; and
A step 220 of determining whether the voltage target value of the first detecting point meets a first closing condition, and if so, determining that the first switch is currently in a closed state.

As can be seen from the above description, the computer-readable storage media for implementing the switch state detection method provided in the embodiment of the present disclosure effectively verifies the validity of the voltage filtering for the detecting point in the circuit, effectively ensures the reliability of the voltage filtering for the detecting point, effectively and reliably prevents the voltage jitter from causing the control misjudgment of the circuit, and is able to effectively improve the accuracy and reliability of the switch state detection in the control guidance unit of the charging base of new energy vehicles based on the filtered voltage, thereby effectively improving the work stability and reliability of the charging base of new energy vehicles.

Persons skilled in the art shall understand that, the embodiments of the present invention may be provided as a method, an apparatus or a computer program product. Therefore, the present invention may be configured with the forms of a full hardware example, a full software example, or combination of a software example and a hardware example. Moreover, the present invention may be configured with the form of a computer program product that is implemented on one or more computer-usable storage media (including but not limited to a disk memory, a CD-ROM, an optical memory, and etc.) including computer-usable program codes. The invention is described with reference to flow diagrams and/or block diagrams of the method, the device (apparatus) and the computer program product based on the embodiment of the invention. It should be understood that each flow and/or block in the flow diagrams and/or block diagrams, and the combination of the flows and/or blocks in the flow diagrams and/or block diagrams may be achieved by computer program commands. These computer program commands may be provided to a CPU of a general-purpose computer, a special-purpose computer, an embedded processor or other programmable data processing device to produce a machine, so that a device for achieving functions designated in one or more flows in the flow diagrams and/or one or more blocks in the block diagrams may be generated by the command executed by the CPU of the computer or other programmable data processing device. These computer program instructions may also be stored in a computer-readable memory that guides a computer or other programmable data processing device to operate in a special way, so that the instruction stored in the computer-readable memory generates a manufactured product including an instruction device which achieves functions designated in one or more flows in the flow diagrams and/or one or more blocks in the block diagrams.

These computer program instructions may also be loaded on a computer or other programmable data processing device, on which a series of operation steps are executed to generate processing achieved by the computer, so that the instruction executed on the computer or other programmable data processing device is provided for being used in the steps of achieving functions designated in one or more flows in the flow diagrams and/or one or more blocks in the block diagrams.

The invention is configured with specific embodiments to illustrate the principle and implementation way of the invention. The above embodiments are described merely for helping to understand the method and core concept of the invention; in addition, a person skilled in the art may, on the basis of the concept of the invention, make modifications to both of the specific embodiments and application scope. In conclusion, contents disclosed herein should not be understood as limitation to the invention.

1. A voltage filtering method for a detecting point in a circuit, comprising:
continuously collecting multiple voltage data of a detecting point in a target circuit;
respectively obtaining a plurality of voltage filtering values corresponding to the detecting point by preforming filter modes based on the multiple voltage data; and
comparing the plurality of voltage filtering values, and if the corresponding comparison result meets a preset condition, determining a voltage target value of the detecting point based on the plurality of voltage filtering values.

2. The voltage filtering method for a detecting point according to claim 1, wherein if the comparison result does not meet the preset condition, then continuously collecting multiple voltage data of the detecting point again and obtaining a plurality of voltage filtering values corresponding to the detecting point again, until a comparison result obtained again meets the preset condition and the voltage target value of the detecting point is determined.

3. The voltage filtering method for a detecting point according to claim 1, wherein the step of respectively obtaining the plurality of voltage filtering values corresponding to the detecting point by applying the filter modes based on the multiple voltage data comprises:
performing a mean filter algorithm to calculate the mean value of the plurality of voltage data of the detecting point, to obtain a voltage mean value as a voltage filtering value of the detecting point; and
performing a median filter algorithm to calculate the median value of the plurality of voltage data of the detecting point, to obtain a voltage median value as another voltage filtering value of the detecting point.

4. The voltage filtering method for a detecting point according to claim 3, wherein if the corresponding comparison result meets the preset condition, determining the voltage target value of the detecting point based on the plurality of voltage filtering values comprises:
obtaining a difference value between the voltage mean value and the voltage median value and determining whether the difference value is smaller than the error threshold value, and if it is, determining the voltage target value of the detecting point based on the voltage mean value and the voltage median value.

5. A switch state detection method, comprising:
obtaining a voltage target value of a first detecting point after controlling a first switch to be closed, based on a voltage filtering method for a detecting point according to claim 1, wherein one end of the first switch is connected with a first resistor in the control guidance unit of a charging base, and the first detecting point is arranged at the other end of the first switch; and
determining whether the voltage target value of the first detecting point meets a first closing condition, and if so, determining that the first switch is currently in a closed state.

6. The switch state detection method according to claim 5, wherein the charging base is a compatible new energy vehicle charging base configured to compatibility with multiple charging protocols.

7. The switch state detection method according to claim 6, wherein the first closing condition comprises:
the voltage target value of the first detecting point obtained after the first switch is controlled to be closed is not equal to the voltage target value of the first detecting point obtained in advance before the first switch is controlled to be closed, and the voltage target value of the first detecting point obtained after the first switch is controlled to be closed is within the voltage range corresponding to either of the charging protocols.

8. The switch state detection method according to claim 6, wherein after the determining that the first switch is currently in the closed state, the switch state detection method further comprises:
determining a target charging protocol corresponding to the voltage target value based on a preset voltage range corresponding to each of the charging protocols.

9. The switch state detection method according to claim 8, wherein after determining the target charging protocol corresponding to the voltage target value, the switch state detection method further comprises:
receiving a closing instruction for the second switch and controlling the second switch to close, wherein one end of the second switch is connected in series with the second resistor in the control guidance unit to form a first branch, the first branch is connected in parallel with a branch where the first resistor is located;
obtaining a voltage target value of the second detecting point based on the voltage filtering method for a detecting point, wherein a branch where the second detecting point is located is connected with the first branch; and
determining whether the voltage target value of the second detecting point meets a second closing condition, and if so, determining that the second switch is currently in a closed state.

10. The switch state detection method according to claim 9, wherein the second closing condition comprises:
the voltage target value of the second detecting point obtained after the second switch is controlled to be closed is not equal to the voltage target value of the second detecting point obtained in advance before the second switch is controlled to be closed.

11. The switch state detection method according to claim 9, wherein after determining that the second switch is currently in a closed state, the switch state detection method further comprises:
receiving a closing instruction for a selection switch, wherein the selection switch is arranged on a second branch which is respectively connected in parallel with the branch where the first resistor is located and the first branch;
controlling the selection switch to close to the control point corresponding to the target charging protocol based on the target charging protocol; wherein the control points corresponding to the charging protocols corresponding to one end of the selection switch are respectively connected with a resistor, and the other end of the selection switch is connected with the branch where the second detecting point is located;
obtaining again a voltage target value of the second detecting point based on the voltage filtering method for the detecting point; and
determining whether the voltage target value of the second detecting point that is obtained after the selection switch is controlled to close meets a third closing condition, and if so, determining that the selection switch is currently in a closed state.

12. The switch state detection method according to claim 11, wherein the third closing condition comprises:
the voltage target value of the second detecting point obtained after the selection switch is controlled to be closed is not equal to the voltage target value of the second detecting point obtained in advance before the selection switch is controlled to be closed.

13. The switch state detection method according to claim 7, wherein each of the charging protocols comprises a ChaoJi charging standard, a GB 2015 charging standard and a CHAdeMO charging standard.

14. A voltage filtering apparatus for a detecting point in a circuit, comprising:
a voltage collection module configured to continuously collect multiple voltage data of a detecting point in a target circuit;
a voltage filtering module configured to respectively obtain a plurality of voltage filtering values corresponding to the detecting point by preforming filter modes based on the multiple voltage data; and
a microcontroller configured to compare the plurality of voltage filtering values, and if the corresponding comparison result meets a preset condition, determine a voltage target value of the detecting point based on the plurality of voltage filtering values.

15. The voltage filtering apparatus for a detecting point according to claim 14, wherein the microcontroller is further configured to perform the following operation:
if the comparison result does not meet the preset condition, controlling the voltage collection module to continuously collect multiple voltage data of the detecting point again and controlling the voltage filtering module to obtain a plurality of voltage filtering values corresponding to the detecting point again, until a comparison result obtained by the microcontroller again meets the preset condition and the voltage target value of the detecting point is determined.

16. The voltage filtering apparatus for a detecting point according to claim 14, wherein the voltage filtering module comprises:
a mean filter unit configured to perform a mean filter algorithm to calculate the mean value of the plurality of voltage data of the detecting point, to obtain a voltage mean value as a voltage filtering value of the detecting point; and
a median filter unit configured to perform a median filter algorithm to calculate the median value of the plurality of voltage data of the detecting point, to obtain a voltage median value as another voltage filtering value of the detecting point.

17. The voltage filtering apparatus for a detecting point according to claim 16, wherein the microcontroller comprises:
an error determination unit configured to obtain a difference value between the voltage mean value and the voltage median value and determining whether the difference value is smaller than the error threshold value, and if it is, determine the voltage target value of the detecting point based on the voltage mean value and the voltage median value.

18-28. (canceled)

29. The voltage filtering method for a detecting point according to claim 2, wherein the step of respectively obtaining the plurality of voltage filtering values corresponding to the detecting point by applying the filter modes based on the multiple voltage data comprises:
performing a mean filter algorithm to calculate the mean value of the plurality of voltage data of the detecting point, to obtain a voltage mean value as a voltage filtering value of the detecting point; and
performing a median filter algorithm to calculate the median value of the plurality of voltage data of the detecting point, to obtain a voltage median value as another voltage filtering value of the detecting point.

30. The voltage filtering method for a detecting point according to claim 29, wherein the comparing the plurality of voltage filtering values, and if the corresponding comparison result meets the preset condition, determining the voltage target value of the detecting point based on the plurality of voltage filtering values, comprises:
obtaining a difference value between the voltage mean value and the voltage median value and determining whether the difference value is smaller than the error threshold value, and if it is, determining the voltage target value of the detecting point based on the voltage mean value and the voltage median value.
